(19) United States
(12) Patent Application Publication
(10) Pub. No.: US 2014/0048895 A1
(43) Pub. Date: Feb. 20, 2014

(54) Magnetic Tunnel Junction Device

(71) Applicant: INDUSTRIAL TECHNOLOGY RESEARCH INSTITUTE, Hsinchu (TW)

(72) Inventors: Sheng-Huang Huang, Tainan City (TW); Kuei-Hung Shen, Hsinchu City (TW); Yung-Hung Wang, Zhubei City (TW)

(73) Assignee: Industrial Technology Research Institute, Hsinchu (TW)

(21) Appl. No.: 13/839,394

(22) Filed: Mar. 15, 2013

Related U.S. Application Data
(60) Provisional application No. 61/684,816, filed on Aug. 20, 2012.
(60) Provisional application No. 61/735,149, filed on Dec. 10, 2012.

(51) Int. Cl. H01L 43/02; H01L 43/12

(52) U.S. Cl. CPC H01L 43/02; H01L 43/12
USPC 257/421; 438/3

(57) ABSTRACT

A magnetic tunnel junction (MTJ) device includes a reference layer having a surface, a tunnel insulating layer formed over the surface of the reference layer, and a free layer formed over the tunnel insulating layer. A magnetization direction in each of the reference layer and the free layer is substantially perpendicular to the surface. A dimension of the reference layer in a horizontal direction substantially parallel to the surface is larger than a dimension of the free layer in the horizontal direction.

### CROSS-REFERENCE TO RELATED APPLICATIONS

This application is based upon and claims the benefit of priority from prior Provisional Application No. 61/684,816, filed Aug. 20, 2012, and prior Provisional Application No. 61/735,149, filed Dec. 10, 2012, the entire contents of both of which are incorporated herein by reference.

### TECHNOLOGY FIELD

The disclosure relates to magnetic tunnel junction devices and to a perpendicular magnetized magnetic tunnel junction device.

### BACKGROUND

Magnetic random access memory (MRAM) is a type of non-volatile random-access memory. An MRAM usually includes a magnetic tunnel junction (MTJ) structure including two magnetic layers separated by a thin tunnel insulating layer. The resistance of the MTJ structure depends on whether the magnetization directions in the two magnetic layers are the same or opposite to each other. Thus, the MTJ structure can switch between a low-resistance state and a high-resistance state. The two different resistance states can be used to represent “0” and “1,” respectively,

MRAM has a performance similar to that of static random-access memory (SRAM), a density similar to that of dynamic random-access memory (DRAM), but lower power consumption than DRAM. MRAM is faster and suffers no degradation over time in comparison to flash memory. Therefore, MRAM is considered as a good candidate for replacing SRAM, DRAM, and flash memory.

An MRAM usually uses in-plane magnetic anisotropy (IMA) materials in the magnetic layers of the MTJ structure. In such an MTJ structure, the magnetization directions in the magnetic layers are parallel to a surface of the magnetic layers. When the device size is reduced, it may not be able to achieve a low write current and a thermal stability in an in-plane MTJ structure at the same time.

### SUMMARY

In accordance with the disclosure, there is provided a magnetic tunnel junction (MTJ) device comprising a reference layer having a surface, a tunnel insulating layer formed over the surface of the reference layer, and a free layer formed over the tunnel insulating layer. A magnetization direction in each of the reference layer and the free layer is substantially perpendicular to the surface. A dimension of the reference layer in a horizontal direction substantially parallel to the surface is larger than a dimension of the free layer in the horizontal direction.

Also in accordance with the disclosure, there is provided a method for forming a magnetic tunnel junction device. The method comprises forming a first ferromagnetic material layer over a substrate, forming a tunnel insulating material layer over the first ferromagnetic material layer, forming a second ferromagnetic material layer over the tunnel insulating material layer, and forming a first etching mask over the second ferromagnetic material layer. The first etching mask covers a first portion of the second ferromagnetic material layer. The method also comprises etching, using the first etching mask as a mask, the second ferromagnetic material layer, the tunnel insulating material layer, and the first ferromagnetic material layer. The method further comprises forming a second etching mask over the second ferromagnetic material layer. The second etching mask covers a second portion of the second ferromagnetic material layer, and the second portion is smaller than the first portion. The method further comprises etching, using the second etching mask as a mask, the second ferromagnetic material layer.

Features and advantages consistent with the disclosure will be set forth in part in the description which follows, and in part will be obvious from the description, or may be learned by practice of the disclosure. Such features and advantages will be realized and attained by means of the elements and combinations particularly pointed out in the appended claims.

It is to be understood that both the foregoing general description and the following detailed description are exemplary and explanatory only and are not restrictive of the invention, as claimed.

The accompanying drawings, which are incorporated in and constitute a part of this specification, illustrate several embodiments of the invention and together with the description, serve to explain the principles of the invention.

### BRIEF DESCRIPTION OF THE DRAWINGS

FIGS. 1(A) and 1(B) are plan view and cross-sectional view, respectively, schematically showing a magnetic tunnel junction (MTJ) device according to an exemplary embodiment.

FIGS. 2(A)-2(C) show results of simulation of the MTJ device shown in FIGS. 1(A) and 1(B) with different parameters.

FIG. 3 is a cross-sectional view schematically showing an MTJ device according to another exemplary embodiment.

FIGS. 4(A) and 4(B) show results of simulation of he MTJ device shown in FIG. 3 with different parameters.

FIGS. 5(A) and 5(B) show results of comparison simulation of the MTJ device shown in FIGS. 1(A) and 1(B) with different parameters.

FIGS. 6(A) and 6(B) compare results of simulations of the MTJ device shown in FIGS. 1(A) and 1(B) and the MTJ device shown in FIG. 3.

FIG. 7 is a cross-sectional view schematically showing an MTJ device according to a further exemplary embodiment.

FIGS. 8(A)-8(H) schematically show a manufacturing process for making the MTJ device shown in FIGS. 1(A) and 1(B).

FIGS. 9(A)-9(H) schematically show a manufacturing process for making the MTJ device shown in FIG. 3.

FIGS. 10(A)-10(F) schematically show additional steps in a manufacturing process for making the MTJ device shown in FIG. 7.

### DESCRIPTION OF THE EMBODIMENTS

Embodiments consistent with the disclosure include a magnetic tunnel junction device and a method of making a magnetic tunnel junction device.

Hereinafter, embodiments consistent with the disclosure will be described with reference to drawings. Wherever possible, the same reference numbers will be used throughout the drawings to refer to the same or like parts.

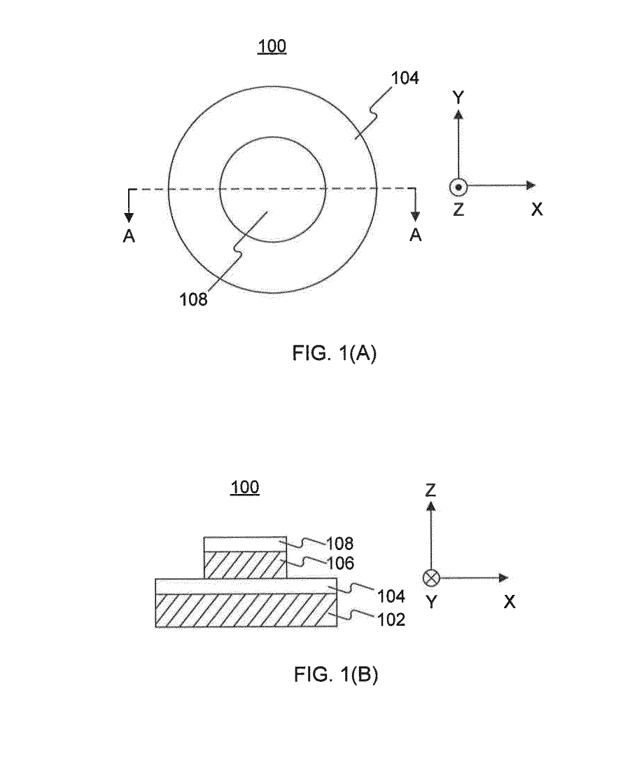

FIGS. 1(A) and 1(B) schematically show a magnetic tunnel junction (MTJ) device 100 consistent with embodiments of the disclosure. FIG. 1(A) is a plan view, and FIG. 1(B) is a cross-sectional view along line A-A shown in FIG. 1(A). As shown in FIG. 1(A), the MTJ device 100 has a circular shape in the plan view. However, the MTJ device 100 is not required to have a circular shape in the plan view, but may have another shape, such as, for example, a triangular shape, a square shape, a diamond shape, a rectangular shape, a hexagonal shape, or an octagonal shape.

The MTJ device 100 includes a reference layer 102 having a surface, a tunnel insulating layer 104 formed over the surface of the reference layer 102, and a free layer 106 formed over the tunnel insulating layer 104. The tunnel insulating layer 104 may be formed of a metal oxide, such as an aluminum oxide or a magnesium oxide. A thickness of the tunnel insulating layer 104 may be about 1 nm to about 3 nm. In some embodiments, a dimension of the tunnel insulating layer 104 in a horizontal direction, substantially parallel to the surface of the reference layer 102, is substantially the same as a dimension of the reference layer 102 in the horizontal direction (hereinafter, a dimension in the horizontal direction is referred to as a “horizontal dimension”). In the MTJ device 100 shown in FIG. 1(A), the horizontal dimension of a layer refers to the diameter of that layer. In other embodiments, the horizontal dimension of a layer may refer to another physical length, such as the length of a side if that layer has a triangle shape, a square shape, a diamond shape, a hexagonal shape, or an octagonal shape, or the length of a long side if that layer has a rectangular shape.

The MTJ device 100 also includes a hard mask capping layer 108 formed over the free layer 106. The hard mask capping layer 108 is intended to protect the free layer 106 from destruction resulting from, e.g., etching. The hard mask capping layer 108 may be formed of, for example, tantalum (Ta). In some embodiments, a horizontal dimension of the hard mask capping layer 108 is substantially the same as a horizontal dimension of the free layer 106.

The MTJ device 100 further includes a first electrode (not shown) formed below the reference layer 102 and a second electrode (not shown) formed over the hard mask capping layer 108. The first and second electrodes may be formed of a metal, a metal alloy, or a metal nitride, such as Ta or TaN.

The reference layer 102 and the free layer 106 are each formed of a ferromagnetic material, and may include a single-layer film, a multilayer film, or laminated layers of different films. For example, the reference layer 102 may include a CoFeB single-layer film, a Co/Pt multilayer film, a Co/Pd multilayer film, a Co/Ni multilayer film, a CoPd alloy, or a FePt alloy, or a laminated layer including any combination thereof. A magnetization in the reference layer 102 may be adjusted by changing thicknesses of the layers in the reference layer 102, or by changing the number of the layers composing the reference layer 102. In some embodiments, an interface of the reference layer 102 contacting the tunnel insulating layer 104 may be CoFeB, to achieve a high tunneling magnetoresistance (TMR) ratio. Similarly, the free layer 106 may include a CoFeB single-layer film, a Co/Pt multilayer film, a Co/Pd multilayer film, a Co/Ni multilayer film, a CoPd alloy, or a FePt alloy, or a laminated layer including any combination thereof. An interface of the free layer 106 contacting the tunnel insulating layer 104 may be CoFeB, to achieve a high TMR ratio.

Consistent with embodiments of the disclosure, in each of the reference layer 102 and the free layer 106, a magnetization direction is substantially perpendicular to the surface of the reference layer 102. Thus the MTJ device 100 is a perpendicular MTJ (p-MTJ) device. The magnetization direction in the reference layer 102 can be fixed and may point upward or downward. The magnetization direction in the free layer 106 is switchable, i.e., may be switched between pointing upward or downward. The magnetization direction in the free layer 106 may be switched by applying an external magnetic field.

The reference layer 102 generates a magnetic field that extends to the outside of the reference layer 102, forming a dipole field. Such dipole field may reach the position where the free layer 106 is located, and thus affect the switching of the magnetization direction in the free layer 106. As a result, the hysteresis loop of the device may become asymmetric.

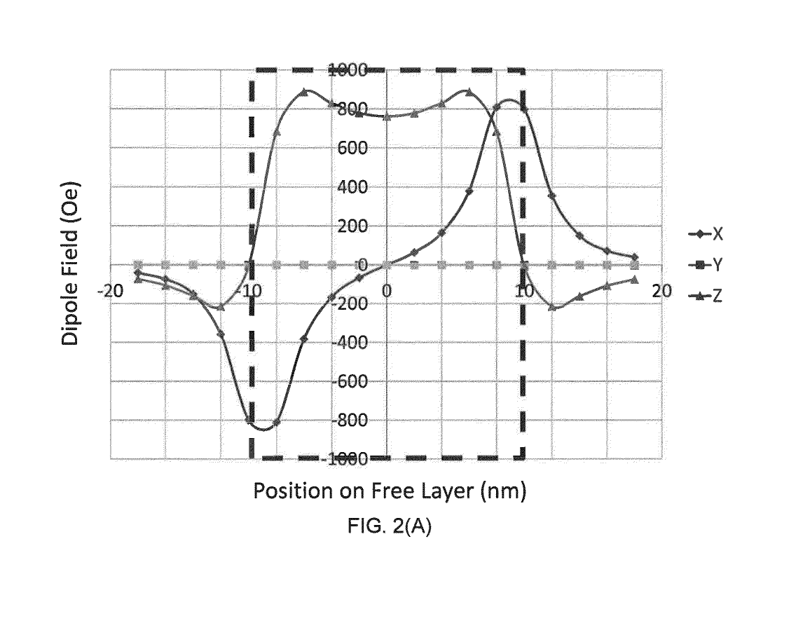

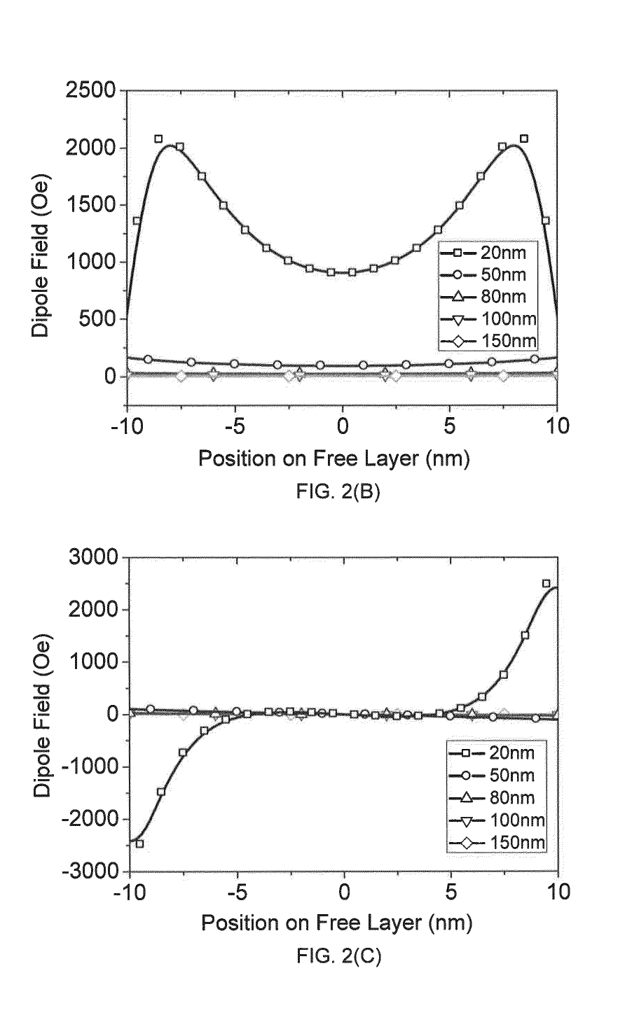

FIGS. 2(A)-2(C) show simulation results, calculated according to micromagnetics, of a magnetic field intensity of the dipole field generated by the reference layer 102 at different positions on a plane on which a lower surface of the free layer 106 is located. In this simulation, each layer in the MTJ device 100 is set to have a circular shape when viewed from the top (i.e., in the plan view), with the different circular layers being concentric, i.e., having their respective centers overlapping each other, as shown in FIG. 1(A). FIGS. 1(A) and 1(B) also schematically show Cartesian coordinates used in the simulation, with coordinate origin being placed at the circle center of the lower surface of the free layer 106, and the X-axis overlapping the line A-A in FIG. 1(A).

In the simulation, a diameter of the free layer 106 in the horizontal direction is set to be 20 nm. A thickness of the tunnel layer 104 is set to be 10 Å, that is, a vertical distance between the reference layer 102 and the free layer 106 is 10 Å. A saturation magnetization of the reference layer 102 is set to be 1250 emu/cm³.

In each of FIGS. 2(A)-2(C), the abscissa represents positions on the X-axis, and the ordinate represents the magnetic field intensity of the dipole field. FIG. 2(A) shows a distribution of each of the three components of the magnetic field intensity of the dipole field, i.e., the X-component, the Y-component, and the Z-component, along the X-axis. In FIG. 2(A), the curve with diamond points represents the distribution of the X-component of the magnetic field intensity of the dipole field, the curve with square points represents the distribution of the Y-component of the magnetic field intensity of the dipole field, and the curve with triangle points represents the distribution of the Z-component of the magnetic field intensity of the dipole field. The results shown in FIG. 2(A) are obtained by setting a diameter of the reference layer 102 to be 20 nm, i.e., the same as that of the free layer 106. It can be seen that both the X-component and the Z component of the magnetic field intensity of the dipole field are high at most positions on the free layer 106.

FIGS. 2(B) and 2(C) show how distributions of the Z-component and the X-component, respectively, of the magnetic field intensity of the dipole field along the X-axis change when the diameter of the reference layer 102 changes. In FIGS. 2(B) and 2(C), curves with square points, curves with circle points, curves with triangle points, curves with inverted triangle points, and curves with diamond points represent the distributions when the diameter of the reference layer 102 is 20 nm, 50 nm, 80 nm, 100 nm, and 150 nm, respectively.

It can be seen from FIGS. 2(B) and 2(C) that, with increasing diameter of the reference layer 102, the magnetic field intensity of the dipole field at the free layer 106 becomes lower and, consequently, the impact of the dipole field generated by the reference layer 102 on the free layer 106 becomes smaller. For example, when the diameter of the reference layer 102 is 50 nm or larger, i.e., 30 nm or more than 30 nm larger than the diameter of the free layer 106, the magnetic field intensity of the dipole field at the free layer 106 becomes much lower as compared to the situation when the diameter of the reference layer 102 is the same as that of the free layer 106. Consequently, the impact of the dipole field generated by the reference layer 102 on the free layer 106 becomes much less significant.

Referring back to FIG. 1(B), consistent with embodiments of the disclosure, the horizontal dimension of the reference layer 102 is larger than the horizontal dimension of the free layer 106. In some embodiments, the horizontal dimension of the free layer 106 may be about 10 nm to about 100 nm, and the horizontal dimension of the reference layer 102 may be at least about 20 nm larger than the dimension of the free layer 106. In some embodiments, the horizontal dimension of the reference layer 102 may be about 20 nm to about 100 nm larger than the horizontal dimension of the free layer 106, or may be about 30 nm to about 60 nm larger than the horizontal dimension of the free layer 106.

In some embodiments, the surface of the reference layer 102 may be a flat surface. The horizontal dimension of the reference layer 102 in the horizontal direction is measured at the surface of the reference layer 102 over which the tunnel insulating layer 104 is disposed.

In some embodiments, cross sections of the reference layer 102, the tunnel insulating layer 104, and the free layer 106 have a rectangular shape, such as shown in FIG. 1(B).

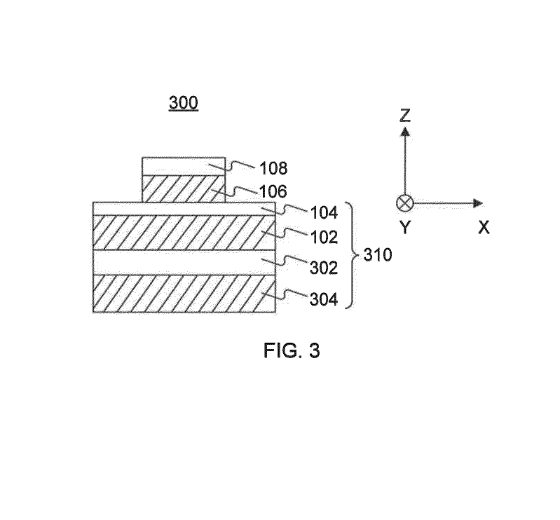

FIG. 3 is a cross-sectional view schematically showing another MTJ device 300 consistent with embodiments of the disclosure. The MTJ device 300 is similar to the MTJ device 100, except that the MTJ device 300 further includes a spacer layer 302 formed below the reference layer 102 and a lower reference layer 304 formed below the spacer layer 302. In some embodiments, the horizontal dimension of the reference layer 102, a horizontal dimension of the spacer layer 302, and a horizontal dimension of the lower reference layer 304 are the same.

The spacer layer 302 is formed of, for example, Ru. A thickness of the spacer layer 302 may be about 0.7 nm to about 1 nm.

Consistent with embodiments of the disclosure, the lower reference layer 304 is formed of a ferromagnetic material, and may include a single-layer film, a multilayer film, or laminated layers of different films. For example, the lower reference layer 304 may include a CoFeB single-layer film, a Co/Pt multilayer film, a Co/Pd multilayer film, a Co/Ni multilayer film, a CoPd alloy, or a FePt alloy, or a laminated layer including any combination thereof.

A magnetization direction in the lower reference layer 304 is fixed and substantially perpendicular to the surface of the reference layer 102. The magnetization direction in the lower reference layer 304 is substantially opposite to the magnetization direction in the reference layer 102. For example, in some embodiments, the magnetization direction in the reference layer 102 points upward, and the magnetization direction in the lower reference layer 304 points downward. Therefore, the reference layer 102, the spacer layer 302, and the lower reference layer 304 form a synthetic antiferromagnetic (SAF) structure 310 having an anti-parallel magnetization configuration. Such an anti-parallel magnetization configuration is a result due to Ruderman-Kittel-Kasuya-Yosida (RKKY) coupling.

Similar to the reference layer 102, the magnetization in the lower reference layer 304 may also be adjusted by changing thicknesses of the layers in the lower reference layer 304, or by changing the number of the layers in the lower reference layer 304.

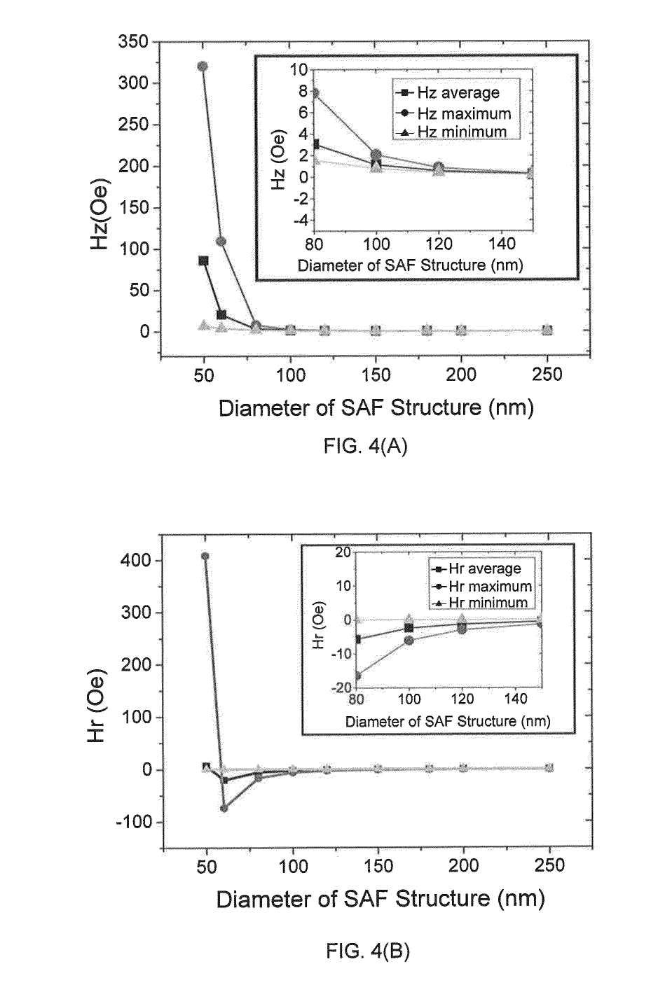

FIGS. 4(A) and 4(B) show simulation results, calculated according to micromagnetics, of a magnetic field intensity of the dipole field generated by the SAF structure 310 of the MTJ device 300 on the plane on which the lower surface of the free layer 106 is located. In this simulation, each layer in the MTJ device 300 is set to have a circular shape when viewed from the top (i.e., in a plan view), with the different circular layers being concentric, i.e., having their respective centers overlapping each other (similar to that shown in FIG. 1(A)). The Cartesian coordinates used in the simulation is also schematically shown in FIG. 3, with the coordinate origin being placed at the circular center of the lower surface of the free layer 106, and the X-axis overlapping the line along which the cross-sectional view of FIG. 3 is shown.

In the simulation, the diameter of the free layer 106 in the horizontal direction is set to be 50 nm. A thickness of the tunnel layer 104 is set to be 20 Å. A thickness of the reference layer 102, a thickness of the spacer layer 302, and a thickness of the lower reference layer 304 are all set to be 10 Å. Thus, the vertical distance between the reference layer 102 and the free layer 106 is 10 Å, and a vertical distance between the lower reference layer 304 and the free layer 106 is 30 Å. The saturation magnetization of the reference layer 102 and that of the lower reference layer 304 are both set to be 1000 emu/cm³. A diameter of the SAF structure 310 in the horizontal direction, i.e., the diameter of both the reference layer 102 and the lower reference layer 304, varies from 50 nm to 250 nm.

In each of FIGS. 4(A) and 4(B), the abscissa represents the diameter of the SAF structure 310, and the ordinate represents the magnetic field intensity of the dipole field. FIG. 4(A) shows the change of the out-of-plane component (H_{z}), i.e., the Z-component, of the magnetic field intensity of the dipole field with changing diameter of the SAF structure 310. FIG. 4(B) shows the change of the in-plane component (Hᵣ) of the magnetic field intensity of the dipole field, i.e., the component of the magnetic field intensity of the dipole field in the X-Y plane (the in-plane component being equal to the X-component with changing diameter of the SAF structure 310. In FIGS. 4(A) and 4(B), the curves with solid circle points represent the maximum values of the out-of-plane component and the in-plane component of the magnetic field intensity of the dipole field, usually achieved at an edge of the free layer 106. The curves with solid triangle points represent the minimum values of the out-of-plane component and the in-plane component of the magnetic field intensity of the dipole field, usually achieved at the center of the free layer 106. The curves with solid square points represent the average values of the out-of-plane component and the in-plane component of the magnetic field intensity of the dipole field, across the free layer 106.

It can be seen from FIGS. 4(A) and 4(B) that, with increasing diameter of the SAF structure 310, the magnetic field intensity of the dipole field at the free layer 106 becomes lower and, consequently, the impact of the dipole field generated by the SAF structure 310 on the free layer 106 becomes smaller. For example, when the diameter of the SAF structure 310 is about 80 nm or larger, i.e., about 30 nm or more than about 30 nm larger than the diameter of the free layer 106, the magnetic field intensity of the dipole field at the free layer 106 becomes much lower as compared to the situation when the diameter of the SAF structure 310 is the same as that of the free layer 106. Consequently, the impact of the dipole field generated by the SAF structure 310 on the free layer 106 becomes much less significant.

To compare the effects of suppressing the impact of dipole field on the free layer 106 achieved in the MTJ device 100 and in the MTJ device 300, a comparison simulation of the MTJ device 100 having dimensions similar to those of the MTJ device 300 is performed. The values of parameters used in this comparison simulation are different from those for the simulation described above with respect to FIG. 2. That is, in the comparison simulation performed of the MTJ device 100, the diameter of the free layer 106 in the horizontal direction is set to be 50 nm. The thickness of the tunnel layer 104 is set to be 20 Å. The thickness of the reference layer 102 is set to be 10 Å. Thus, the vertical distance between the reference layer 102 and the free layer 106 is 10 Å. The saturation magnetization of the reference layer 102 is set to be 1000 emu/cm³. The diameter of the reference layer 102 varies from 50 nm to 250 nm.

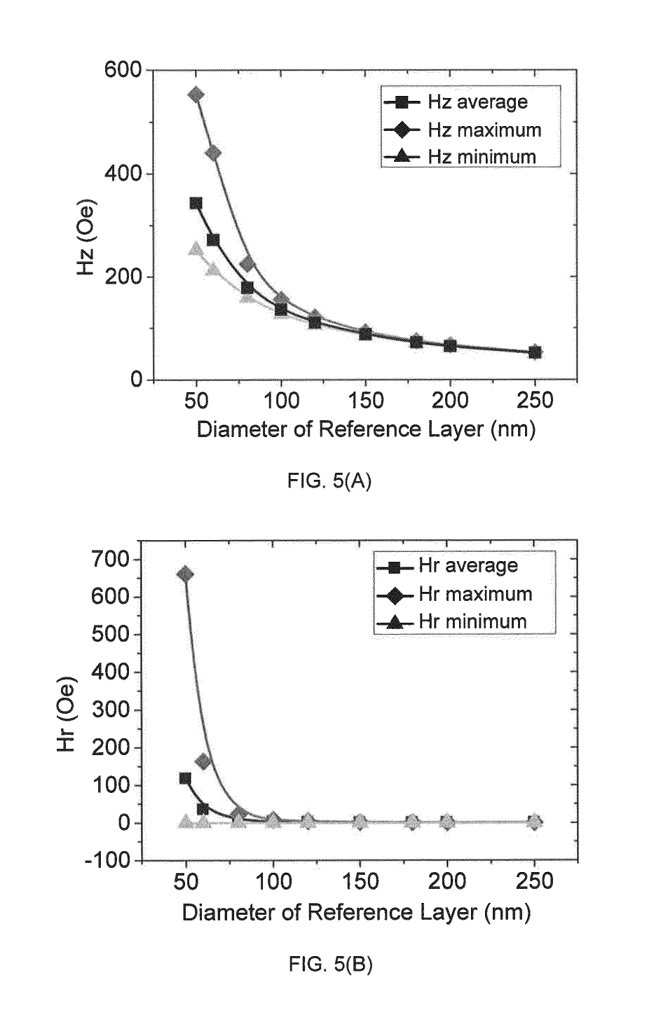

The results of the comparison simulation performed for the MTJ device 100 are shown in FIGS. 5(A) and 5(B), in which the abscissa represents the diameter of the reference layer 102 of the MTJ device 100, and the ordinate represents the magnetic field intensity of the dipole field. FIG. 5(A) shows the change of the out-of-plane component of the magnetic field intensity of the dipole field with changes of the diameter of the reference layer 102. FIG. 5(B) shows the change of the in-plane component of the magnetic field intensity of the dipole field with changes of the diameter of the reference layer 102. The results of this comparison simulation also demonstrate that, with the preset values of parameters listed in the last paragraph, both the out-of-plane and the in-plane components of the magnetic field intensity of the dipole field become much lower when the diameter of the reference layer 102 is about 30 nm or more than about 30 nm larger than the diameter of the free layer 106, as compared to the situation when the diameter of the reference layer 102 is about the same as the diameter of the free layer 106.

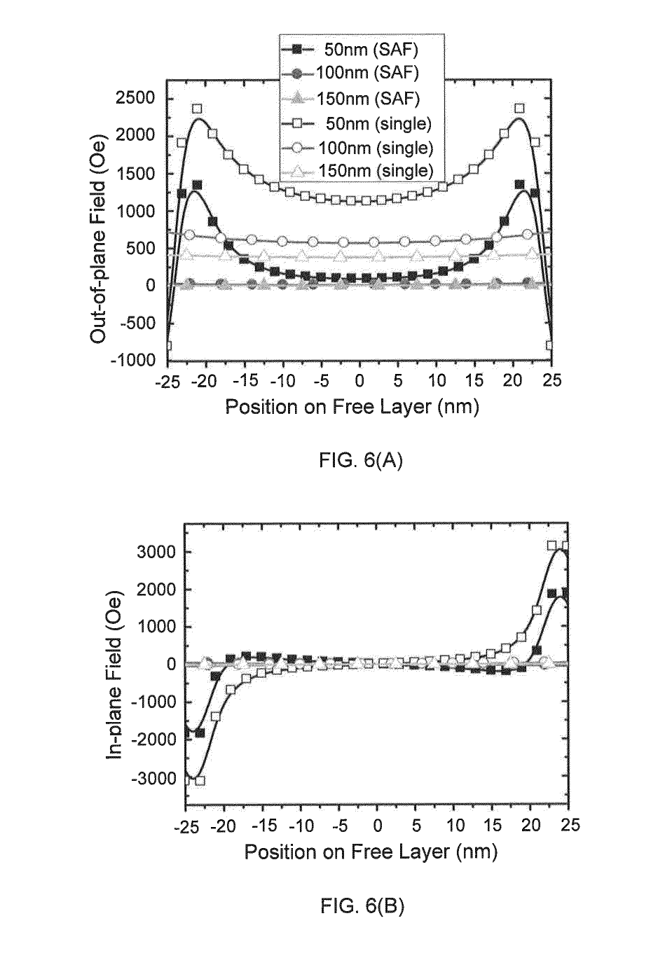

Comparing FIGS. 4(A) and 4(B) with FIGS. 5(A) and 5(B), it is seen that the MTJ device 300 is more effective in suppressing the impact of a dipole field than the MTJ device 100 having similar dimensions. This may be due to the additional lower reference layer 304, which is not present in the MTJ device 100. Such a result can be more clearly seen in FIGS. 6(A) and 6(B) described below, in which the results of the simulation on the MTJ device 300 and the results of the comparison simulation on the MTJ device 100 are shown together in one graph.

In each of FIGS. 6(A) and 6(B), the abscissa represents positions on the X-axis, i.e., positions on the lower surface of the free layer 106. The ordinate represents the magnetic field intensity of the dipole field. FIGS. 6(A) and 6(B) show how distributions of the out-of-plane component and the in-plane component, respectively, of the magnetic field intensity of the dipole field along the X-axis change when the diameter of the reference layer 102 in the MTJ device 100 changes (curves with hollow points, labeled as “single”) or when the diameter of the SAF structure 310 in the MTJ device 300 changes (curves with solid points, labeled as “SAF”). In FIGS. 6(A) and 6(B), curves with hollow square points, curves with hollow circle points, and curves with hollow triangle points represent the distributions when the diameter of the reference layer 102 in the MTJ device 100 is 50 nm, 100 nm, and 150 nm, respectively. Curves with solid square points, curves with solid circle points, and curves with solid triangle points represent the distributions when the diameter of the SAF structure 310 in the MTJ device 300 is 50 nm, 100 nm, and 150 nm, respectively. As can be seen from FIGS. 6(A) and 6(B), the SAF structure 310 in the MTJ device 300 generated a smaller dipole field as compared to the single reference layer 102 in the MTJ device 100. Therefore, the MTJ device 300 has a better capability of suppressing the impact of the dipole field on the free layer 106.

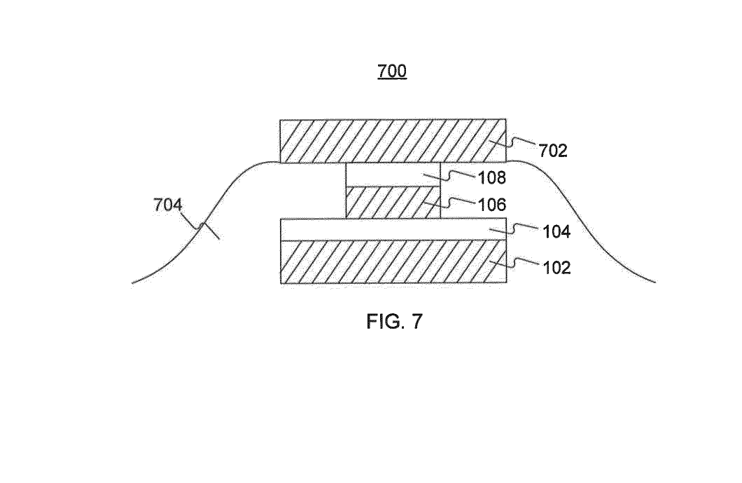

FIG. 7 is a cross-sectional view schematically showing another MTJ device 700 consistent with embodiments of the disclosure. The MTJ device 700 is similar to the MTJ device 100, except that the MTJ device 700 further includes a magnetic capping layer 702 formed over the hard mask capping layer 108. In some embodiments, the horizontal dimension of the reference layer 102 and a horizontal dimension of the magnetic capping layer 702 is the same. That is, the horizontal dimension of the magnetic capping layer 702 is larger than the horizontal dimension of the free layer 106, for example, it may be at least about 20 nm larger, or about 20 nm to about 100 nm larger, or about 30 nm to about 60 nm larger, than the horizontal dimension of the free layer 106.

Consistent with embodiments of the disclosure, the magnetic capping layer 702 is formed of a ferromagnetic material, and may include a single-layer film, a multilayer film, or laminated layers of different films. For example, the magnetic capping layer 702 may include a CoFeB single-layer film, a Co/Pt multilayer film, a Co/Pd multilayer film, a Co/Ni multilayer film, a CoPd alloy, or a FePt alloy, or a laminated layer including any combination thereof.

A magnetization direction in the magnetic capping layer 702 is fixed and substantially perpendicular to the surface of the reference layer 102. The magnetization direction in the magnetic capping layer 702 is substantially opposite to the magnetization direction in the reference layer 102. For example, in some embodiments, the magnetization direction in the reference layer 102 points upward, and the magnetization direction in the magnetic capping layer 702 points downward.

Similar to the reference layer 102, a magnetization in the magnetic capping layer 702 may also be adjusted by changing thicknesses of the layers composing the magnetic capping layer 702, or by changing the number of the layers in the magnetic capping layer 702.

The MTJ device 700 further includes an insulating spacer 704, which covers the hard mask capping layer 108, the free layer 106, the tunnel insulating layer 104, and the reference layer 102. The magnetic capping layer 702 is formed over the insulating spacer 704. The insulating spacer 704 is formed of an insulating material, such as, silicon oxide or silicon nitride.

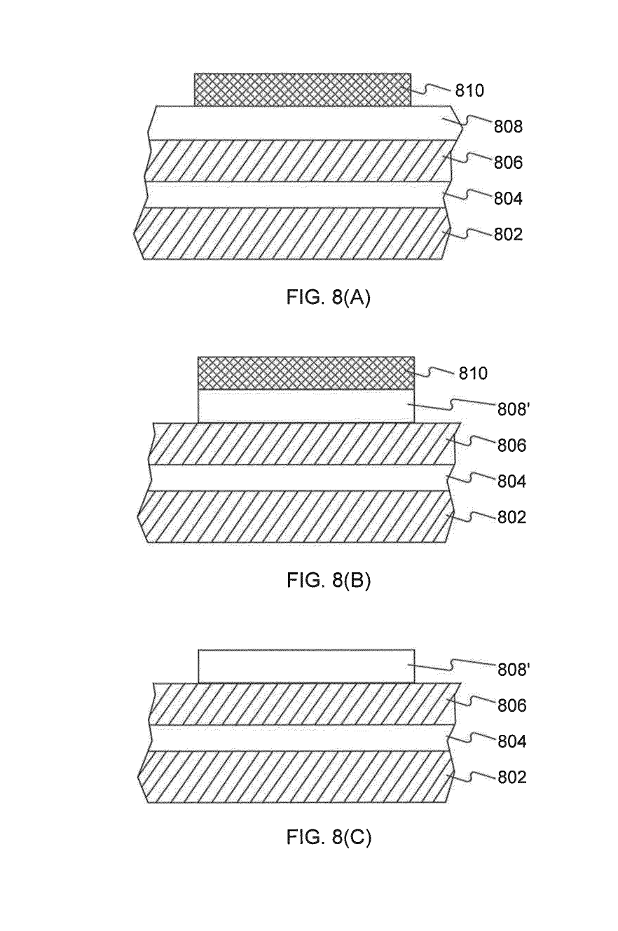

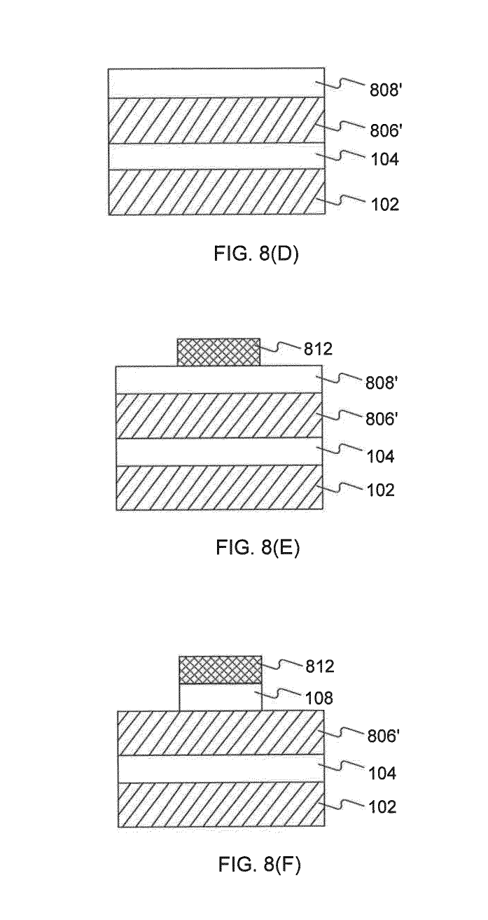

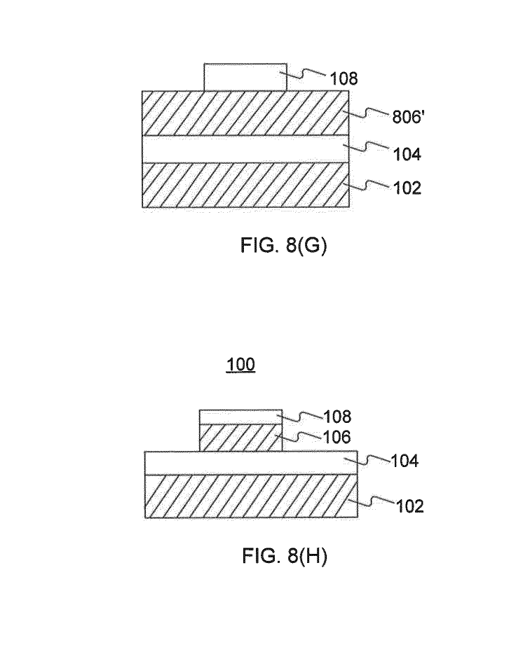

FIGS. 8(A)-8(H) show an exemplary manufacturing process for making the MTJ device 100 shown in FIGS. 1(A) and 1(B). In the exemplary manufacturing process, two etching processes, i.e., first and second etching processes, are performed to define the extent of the reference layer 102 and the tunnel insulating layer 104, and the extent of the free layer 106 and the hard mask capping layer 108, respectively.

As shown in FIG. 8(A), a first ferromagnetic material layer 802, a tunnel insulating material layer 804, a second ferromagnetic material layer 806, and a hard mask material layer 808 are formed over a substrate (not shown). The first etching process is performed to etch portions of the layers 802, 804, 806, and 808, to form the reference layer 102 and the tunnel insulating layer 104. In some embodiments, the first etching process may include several sub-etchings, such as a first sub-etching and a second sub-etching as described in detail below.

As shown in FIG. 8(A), a photo resist layer is formed over the hard mask material layer 808 and patterned to form a first resist pattern 810. The first resist pattern 810 covers a region that corresponds to the reference layer 102. As shown in FIG. 8(B), the first sub-etching is performed, using the first resist pattern 810 as a mask, to remove portions of the layer 808 that are not covered by the first resist pattern 810, forming a hard mask pattern 808′. The first resist pattern 810 is then removed to expose the hard mask pattern 808′, as shown in FIG. 8(C). Using the hard mask pattern 808′ as a mask, the second sub-etching is performed to remove portions of the layers 802, 804, and 806 that are not covered by the hard mask pattern 808′. The second sub-etching may be non-selective with respect to the layers 802, 804, and 806, or may include a series of etchings each etching one or more layers of layers 802, 804, and 806. In some embodiments, the second sub-etching may be an anisotropic etching. After the second sub-etching, the reference layer 102 and the tunnel insulating layer 104 are formed, and the second ferromagnetic material layer 806 is turned into an temporary pattern layer 806′, as shown in FIG. 8(D).

The second etching process is performed to form the free layer 106 and the hard mask capping layer 108. In some embodiments, the second etching process may also include several sub-etchings, such as a third sub-etching and a fourth sub-etching, as described in detail below.

As shown in FIG. 8(E), another photo resist layer is formed over the hard mask pattern 808′ and patterned to form a second resist pattern 812. The second resist pattern 812 covers a region that corresponds to the free layer 106. As shown in FIG. 8(F), using the second resist pattern 812 as a mask, a third sub-etching is performed to remove portions of the hard mask pattern 808′ that are not covered by the second resist pattern 812, forming the hard mask capping layer 108. The second resist pattern 812 is removed to expose the hard mask capping layer 108, as shown in FIG. 8(G). Using the hard mask capping layer 108 as a mask, a fourth sub-etching is performed to remove portions of the temporary pattern layer 806′ that are not covered by the hard mask capping layer 108, forming the free layer 106, as shown in FIG. 8(H). In some embodiments, the fourth sub-etching may be selective with respect to the tunnel insulating material in the tunnel insulating layer 104, so that the fourth sub-etching stops at a surface of the tunnel insulating layer 104, or may etch a small portion of the tunnel insulating layer 104. After the second etching process, the free layer 106 and the hard mask capping layer 108 are formed, as shown in FIG. 8(H).

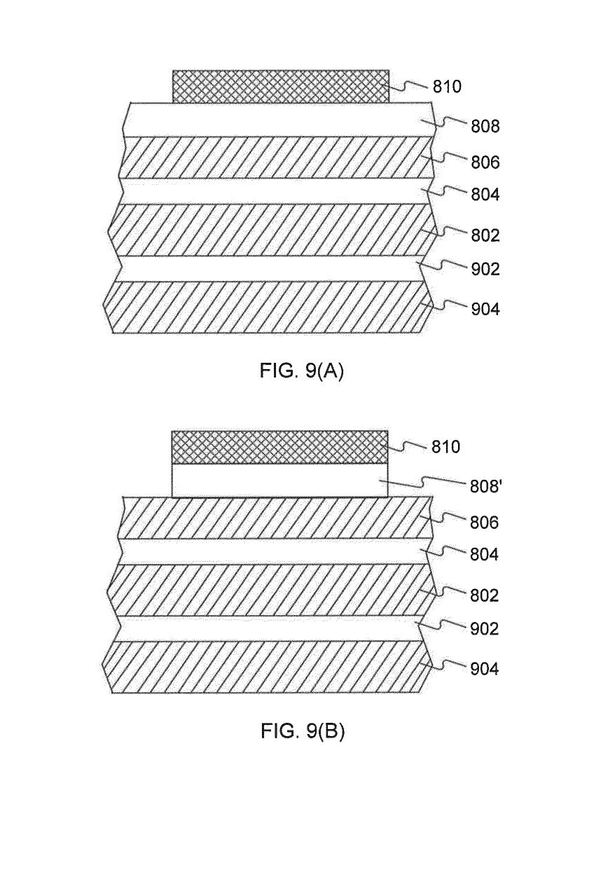

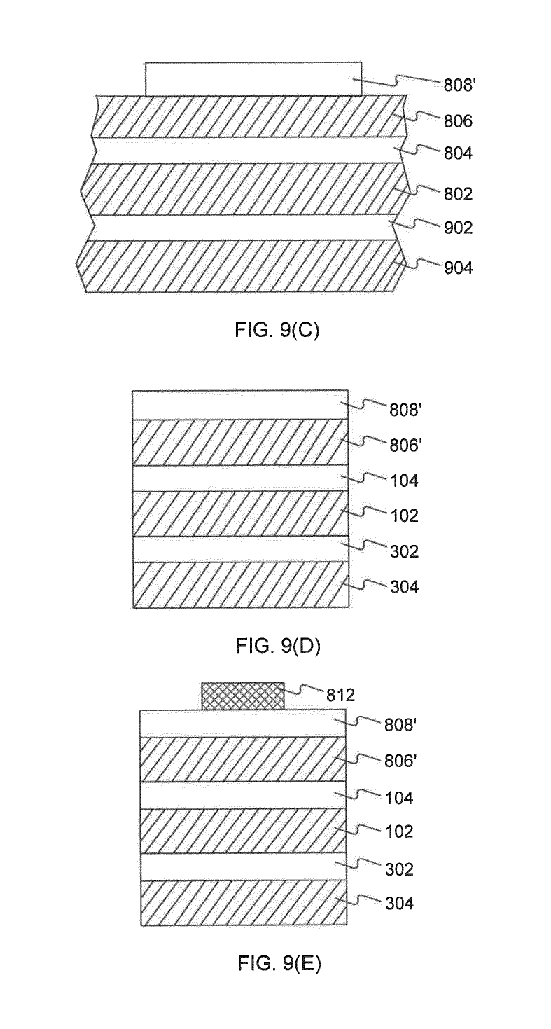

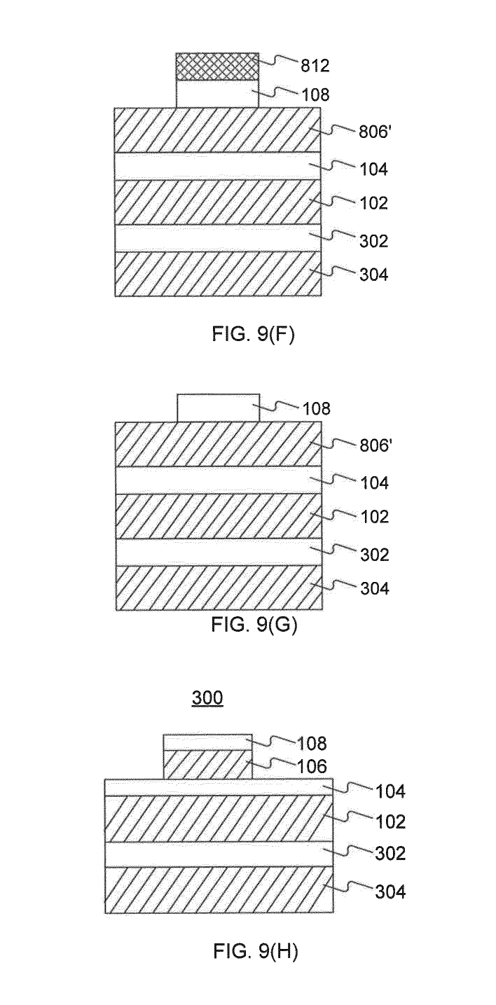

FIGS. 9(A)-9(H) show an exemplary manufacturing process for making the MTJ device 300 shown in FIG. 3. The process shown in FIGS. 9(A)-9(H) is similar to that shown in FIGS. 8(A)-8(H), except that two more layers, i.e., a spacer material layer 902 and a third ferromagnetic material layer 904 are formed below the first ferromagnetic material layer 802, as shown in FIG. 9(A). In the exemplary manufacturing process shown in FIGS. 9(A)-9(H), two etching processes, i.e., first and second etching processes, are also performed to define the extent of the lower reference layer 304, the spacer layer 302, the reference layer 102 and the tunnel insulating layer 104, and the extent of the free layer 106 and the hard mask capping layer 108, respectively.

The first etching process in the manufacturing of MTJ device 300 also includes a first sub-etching and a second sub-etching. As shown in FIGS. 9(A)-9(C), the first sub-etching is performed to form a hard mask pattern 808′. When performing the second sub-etching, all the layers below the hard mask pattern 808′ are etched, including the spacer material layer 902 and the third ferromagnetic material layer 904, to form the spacer layer 302 and the lower reference layer 304, as shown in FIG. 9(D). The remaining steps (including the second etching process) for forming the free layer 106 and the hard mask capping layer 108 as shown in FIGS. 9(E)-9(H) are the same as the steps for forming the free layer 106 and the hard mask capping layer 108 shown in FIGS. 8(E)-8(H).

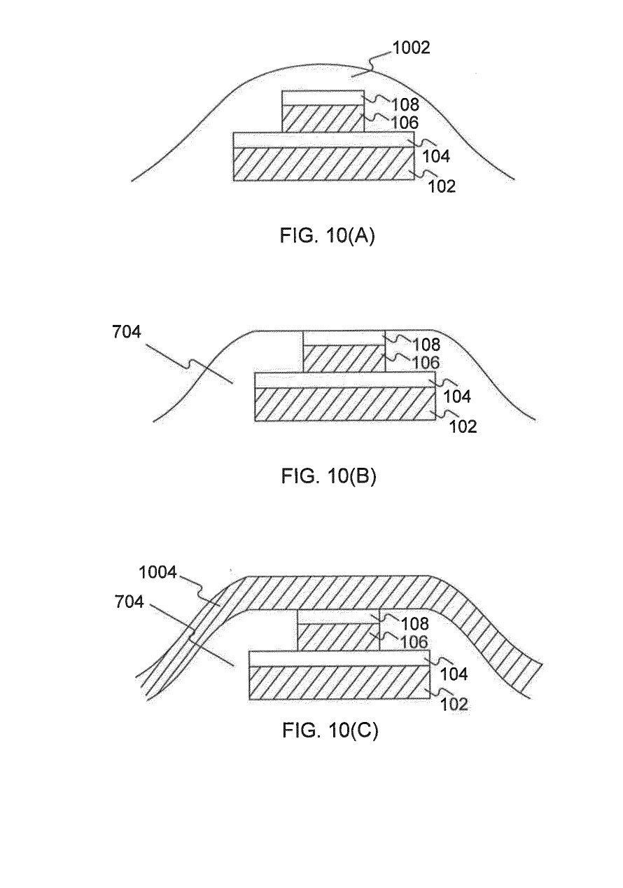

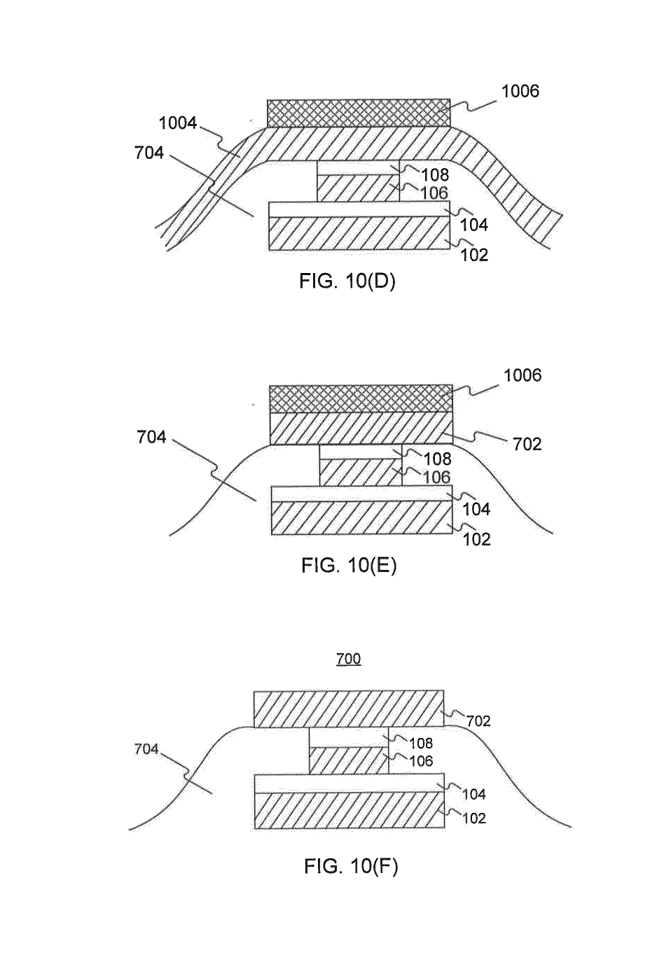

For the MTJ device 700 shown in FIG. 7, the manufacturing process includes steps of the manufacturing process for making the MTJ device 100 shown in FIG. 1, with additional steps needed to form the insulating spacer 704 and the magnetic capping layer 702. FIGS. 10(A)-10(F) show an example of the additional steps in the manufacturing process for making the MTJ device 700. These additional steps follow the step shown in FIG. 8(H).

As shown in FIG. 10(A), an insulating material layer 1002 is formed to cover the entire device shown in FIG. 8(H). A portion of the insulating material layer 1002 is removed to expose the hard mask capping layer 108, as shown in FIG. 10(B). The portion of the insulating material layer 1002 may be removed by, for example, etching or chemical mechanical polishing (CMP). In some embodiments, an end point detection is employed to make sure the etching or the CMP stops at a top of the hard mask capping layer 108 or removes a small amount of the hard mask capping layer 108. As shown in FIG. 10(C), a fourth ferromagnetic material layer 1004 is formed over the entire device and contacts the hard mask capping layer 108. A photo resist layer is formed over the fourth ferromagnetic material layer 1004 and patterned to form a third resist pattern 1006, as shown in FIG. 10(D). Using the third resist pattern 1006 as a mask, an etching is performed to remove portions of the fourth ferromagnetic material layer 1004 that are not covered by the third resist pattern 1006, forming the magnetic capping layer 702, as shown in FIG. 10(E). After removing the third resist pattern 1006, the MTJ device 700 is formed, as shown in FIG. 10(F).

In other embodiments, the additional steps may include a lift-off process, in which after the insulating material layer 1002 is formed, a photo resist layer is formed over the insulating material layer 1002 and patterned to open a region corresponding to the magnetic capping layer 702. Then a ferromagnetic material layer is formed over the entire device. After that, the patterned photo resist layer is removed, which at the same time removes the ferromagnetic material over the patterned photo resist layer (i.e., the ferromagnetic material outside the region corresponding to the magnetic capping layer 702), leaving the ferromagnetic material in the region corresponding to the magnetic capping layer 702, so as to form the magnetic capping layer 702.

Other embodiments of the disclosure will be apparent to those skilled in the art from consideration of the specification and practice of the invention disclosed herein. It is intended that the specification and examples be considered as exemplary only, with a true scope and spirit of the invention being indicated by the following claims.

1. A magnetic tunnel junction (MTJ) device, comprising:
a reference layer having a surface;
a tunnel insulating layer formed over the surface of the reference layer; and
a free layer formed over the tunnel insulating layer, a magnetization direction in each of the reference layer and the free layer being substantially perpendicular to the surface,
wherein a dimension of the reference layer in a horizontal direction substantially parallel to the surface is larger than a dimension of the free layer in the horizontal direction.

2. The MTJ device of claim 1, wherein the dimension of the reference layer in the horizontal direction is at least about 20 nm larger than the dimension of the free layer in the horizontal direction.

3. The MTJ device of claim 1, wherein the dimension of the reference layer in the horizontal direction is about 20 nm to about 100 nm larger than the dimension of the free layer in the horizontal direction.

4. The MTJ device of claim 1, wherein the dimension of the free layer in the horizontal direction is about 10 nm to about 100 nm.

5. The MTJ device of claim 1, wherein the reference layer includes one of a CoFeB single-layer film, a Co/Pt multilayer film, a Co/Pd multilayer film, a Co/Ni multilayer film, a CoPd alloy, or a FePt alloy, or a laminated layer including any combination thereof.

6. The MTJ device of claim 1, wherein the free layer includes one of a CoFeB single-layer film, a Co/Pt multilayer film, a Co/Pd multilayer film, a Co/Ni multilayer film, a CoPd alloy, or a FePt alloy, or a laminated layer including any combination thereof.

7. The MTJ device of claim 1, further comprising a magnetic capping layer formed over the free layer, a dimension of the magnetic capping layer in the horizontal direction being larger than the dimension of the free layer in the horizontal direction.

8. The MTJ device of claim 7, wherein the dimension of the magnetic capping layer in the horizontal direction is at least about 20 nm larger than the dimension of the free layer in the horizontal direction.

9. The MTJ device of claim 7, wherein a magnetic direction in the magnetic capping layer is substantially perpendicular to the surface and substantially opposite to the magnetic direction in the reference layer.

10. The MTJ device of claim 7, wherein the magnetic capping layer includes one of a CoFeB single-layer film, a Co/Pt multilayer film, a Co/Pd multilayer film, a Co/Ni multilayer film, a CoPd alloy, or a FePt alloy, or a laminated layer including any combination thereof.

11. The MTJ device of claim 1, further comprising:
a spacer layer formed below the reference layer; and
a lower reference layer formed below the spacer layer, a magnetization direction in the lower reference layer being substantially perpendicular to the surface and substantially opposite to the magnetization direction in the reference layer.

12. The MTJ device of claim 11, wherein a dimension of the lower reference layer in the horizontal direction, a dimension of the space layer in the horizontal direction, and the dimension of the reference layer in the horizontal direction are substantially the same.

13. The MTJ device of claim 11, wherein a thickness of the spacer layer is about 0.7 nm to about 1 nm.

14. The MTJ device of claim 11, wherein the spacer layer includes Ru.

15. The MTJ device of claim 1, wherein a dimension of the tunnel insulating layer in the horizontal direction is substantially the same as the dimension of the reference layer in the horizontal direction.

16. The MTJ device of claim 1, wherein a thickness of the tunnel insulating layer is about 1 nm to about 3 nm.

17. The MTJ device of claim 1, wherein the tunnel insulating layer includes metal oxide.

18. The MTJ device of claim 1, further comprising a hard mask capping layer formed over the free layer, a dimension of the hard mask capping layer in the horizontal direction being substantially the same as the dimension of the free layer in the horizontal direction.

19. The MTJ device of claim 18, wherein the hard mask capping layer includes Ta.

20. A method for forming a magnetic tunnel junction device, comprising:
forming a first ferromagnetic material layer over a substrate;
forming a tunnel insulating material layer over the first ferromagnetic material layer;
forming a second ferromagnetic material layer over the tunnel insulating material layer;
forming a first etching mask over the second ferromagnetic material layer, the first etching mask covering a first portion of the second ferromagnetic material layer;
etching, using the first etching mask as a mask, the second ferromagnetic material layer, the tunnel insulating material layer, and the first ferromagnetic material layer;
forming a second etching mask over the second ferromagnetic material layer, the second etching mask covering a second portion of the second ferromagnetic material layer, the second portion being smaller than the first portion; and
etching, using the second etching mask as a mask, the second ferromagnetic material layer.
